(19) United States
(12) Patent Application Publication
(10) Pub. No.: US 2020/0195262 A1
(43) Pub. Date: Jun. 18, 2020

(54) FREQUENCY SYNTHESIZER AND METHOD THEREOF

(71) Applicant: Industrial Technology Research Institute, Hsinchu (TW)

(72) Inventor: Feng-Hsu Chung, Pingtung County (TW)

(73) Assignee: Industrial Technology Research Institute, Hsinchu (TW)

(21) Appl. No.: 16/218,440

(22) Filed: Dec. 12, 2018

(51) Int. Cl. H03L 7/099; H03M 3/00; H03L 7/093; H03J 5/02

(52) U.S. Cl. CPC H03L 7/0992; H03J 5/0272; H03L 7/093; H03M 3/30

(57) ABSTRACT

A frequency synthesizer is provided. The frequency synthesizer includes a jitter-cleaning phase-locked loop, a fractional phase-locked loop, a mixer, and a radio-frequency phase-locked loop. The jitter-cleaning phase-locked loop receives a reference clock and a mixed signal, and suppresses a jitter of the reference clock to generate a first oscillating signal based on the reference clock and the mixed signal. The fractional phase-locked loop receives the reference clock and generates a second oscillating signal based on the reference clock. The mixer mixes the first oscillating signal and the second oscillating signal to generate the mixed signal. The radio-frequency phase-locked loop receives the first oscillating signal and generates an output signal based on the first oscillating signal.

### TECHNICAL FIELD

The disclosure generally relates to a frequency synthesizer and a method thereof.

### BACKGROUND

Generally, a frequency synthesizer would provide a local oscillating signal to a radio frequency transceiver for the purpose of performing frequency up-conversion or down-conversion. In a multi-carrier system, for example, the orthogonal frequency-division multiplexing (OFDM) which transmits a number of low-rate streams in parallel instead of a single high-rate stream for wireless transmission, is used by both 4G and IEEE 802.11 (Wi-Fi). When a phase-locked loop (PLL) of a frequency synthesizer performs frequency up-conversion or down-conversion, the phase noise may be superimposed on OFDM signals, causing the inter carrier interference (ICI) which may degrade the signal quality. Generally, the overall phase noise of the phase-locked loop could be affected by the reference clock, the RF voltage-controlled oscillator, and the loop bandwidth.

### SUMMARY

Accordingly, the present disclosure is directed to a frequency synthesizer, in which a phase-lock loop and a fractional phase-lock loop are combined to provide the jitter-cleaning function and high frequency resolution, and improve the signal quality.

In one of the exemplary embodiments, the present disclosure is directed to a frequency synthesizer which the frequency synthesizer would include, but not limited to, a jitter-cleaning phase-locked loop, a fractional phase-locked loop, a mixer, and a radio-frequency phase-locked loop. The jitter-cleaning phase-locked loop receives a reference clock and a mixed signal, and suppresses a jitter of the reference clock to generate a first oscillating signal based on the reference clock and the mixed signal. The fractional phase-locked loop receives the reference clock, and generates a second oscillating signal based on the reference clock. The mixer is coupled to the jitter-cleaning phase-locked loop and the fractional phase-locked loop. The mixer mixes the first oscillating signal and the second oscillating signal to generate the mixed signal. The radio-frequency phase-locked loop is coupled to the jitter-cleaning phase-locked loop. The radio-frequency phase-locked loop receives the first oscillating signal and generates an output signal based on the first oscillating signal.

In one of the exemplary embodiments, the present disclosure is directed to a frequency synthesizing method used by a frequency synthesizer, wherein the frequency synthesizer comprises a jitter-cleaning phase-locked loop, a fractional phase-locked loop, a mixer, and a radio-frequency phase-locked loop. The frequency synthesizing method would include, but not limited to, suppressing, by the jitter-cleaning phase-locked loop, a jitter of the reference clock to generate a first oscillating signal based on the reference clock and the mixed signal. Generating, by the fractional phase-locked loop, a second oscillating signal based on the reference clock. Mixing, by the mixer, the first oscillating signal and the second oscillating signal to generate the mixed signal. Generating, by the radio-frequency phase-locked loop, an output signal based on the first oscillating signal.

It should be understood, however, that this summary may not contain all of the aspect and embodiments of the present disclosure and is therefore not meant to be limiting or restrictive in any manner. Moreover, the present disclosure would include improvements and modifications. To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic block diagram illustrating a frequency synthesizer according to one of the exemplary embodiments of the disclosure.

FIG. 2 is a circuit block diagram illustrating a frequency synthesizer according to one of the exemplary embodiments of the disclosure.

FIG. 3 are bode plots which illustrates improvement of phase noise by using the frequency synthesizer according of one of the exemplary embodiments of the disclosure.

FIG. 4 illustrates a flow chart of a frequency synthesizing method according to one of the exemplary embodiments of the disclosure.

### DESCRIPTION OF THE EMBODIMENTS

A term “couple” used in the full text of the disclosure (including the claims) refers to any direct and indirect connections. For instance, if a first device is described to be coupled to a second device, it is interpreted as that the first device is directly coupled to the second device, or the first device is indirectly coupled to the second device through other devices or connection means. Moreover, wherever possible, components/members/steps using the same referral numerals in the drawings and description refer to the same or like parts. Components/members/steps using the same referral numerals or using the same terms in different embodiments may cross-refer related descriptions.

As the fifth generation (5G) wireless communication system has been continuously defined by the 3rd Generation Partnership Project (3GPP), various implementation issues would still need to be resolved. The New Radio (NR) of 5G would require a new radio access technology other than Long Term Evolution (LTE), and such technology may need to be sufficiently flexible to support a wider band ranged from 0.5 GHz up to 100 GHz according to 3GPP TR 38.901 version 14.0.0 Release 14. Thus, frequency synthesizers may have been re-designed to meet the new requirements.

However, the carrier frequency as defined by 5G NR falls between 0.5 GHz and 100 GHz so that the reference clock transmitted from a baseband end may include digital noise, which for example, could be generated by a field programmable logical array (FPGA) or other programmable logical circuits. In addition, the baseband of a transmitter or a receiver may have a considerable requirement for the frequency offset caused by temperature. Thus, even though a frequency oscillator has a built-in temperature compensation circuit, the current frequency synthesizer might not meet the new standard of the 5G NR. The degradation by temperature may lead to worsening of phase noises generated by a voltage-controlled oscillator of a frequency synthesizer. As such, if the phase noise of the reference clock can be reduced, the loop bandwidth of the phase-locked loop would be able to be appropriately increased. In addition, the frequency synthesizer for 5G NR transmission must have high frequency resolution based on the channel bandwidth of the 5G NR transmission defined by 3GPP.

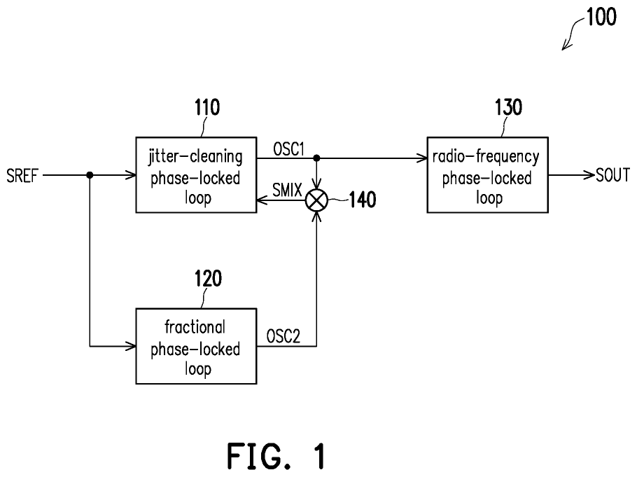

FIG. 1 is a schematic block diagram illustrating a frequency synthesizer according to one of the exemplary embodiments of the disclosure. Referring to FIG. 1, the frequency synthesizer 100 includes a jitter-cleaning phase-locked loop 110, a fractional phase-locked loop 120, a radio-frequency phase-locked loop 130 and a mixer 140, but not limited thereto. In one embodiment of the disclosure, the frequency synthesizer 100 is configured to receive a reference clock SREF, and generate an output signal SOUT with a specific frequency range according to the reference clock SREF.

The jitter-cleaning phase-locked loop 110 is configured to receive a reference clock SREF and a mixed signal SMIX, and suppress a jitter of the reference clock SREF to generate a first oscillating signal OSC1 based on the reference clock SREF and the mixed signal SMIX. Specifically, the jitter-cleaning phase-locked loop 110 can be an integer-N phase-locked loop, but not limited thereto. In one embodiment of the disclosure, the jitter-cleaning phase-locked loop 110 suppresses the jitter of the reference clock SREF to provide a stable and pure first oscillating signal OSC1, and the frequency of the first oscillating signal OSC1 depends on internal circuits of the jitter-cleaning phase-locked loop 110.

The fractional phase-locked loop 120 is configured to receive the reference clock SREF, and generate a second oscillating signal OSC2 based on the reference clock SREF. To be specific, the fractional phase-locked loop 120 can be a fractional-N phase-locked loop, but not limited thereto. In the present embodiment, according to the reference clock SREF, the fractional phase-locked loop 120 provides the second oscillating signal OSC2 with small channel spacing to the mixer 140, and the frequency of the second oscillating signal OSC2 depends on internal circuits of the fractional phase-locked loop 120.

The mixer 140 is coupled to the jitter-cleaning phase-locked loop 110 and the fractional phase-locked loop 120. The mixer 140 is configured to mix the first oscillating signal OSC1 and the second oscillating signal OSC2 to generate the mixed signal SMIX. In one embodiment of the disclosure, the mixer 140 mixes the first oscillating signal OSC1 with frequency f1 and the second oscillating signal OSC2 with frequency f2, and outputs the mixed signal SMIX with a sum or a differential between frequency f1 and frequency f2, depending on the actual requirement. The mixer 140 can be implemented as a double-balanced mixer, but not limited thereto.

The radio-frequency phase-locked loop 130 is coupled to the jitter-cleaning phase-locked loop 110. The radio-frequency phase-locked loop 130 is configured to receive the first oscillating signal OSC1, and generate an output signal SOUT according to the first oscillating signal OSC1. Specifically, the radio-frequency phase-locked loop 130 can be an integer-N phase-locked loop, but not limited thereto. In one embodiment of the disclosure, the radio-frequency phase-locked loop 130 can provide an output signal SOUT with radio frequency. The frequency of the output signal depends on internal circuits of the radio-frequency phase-locked loop 130.

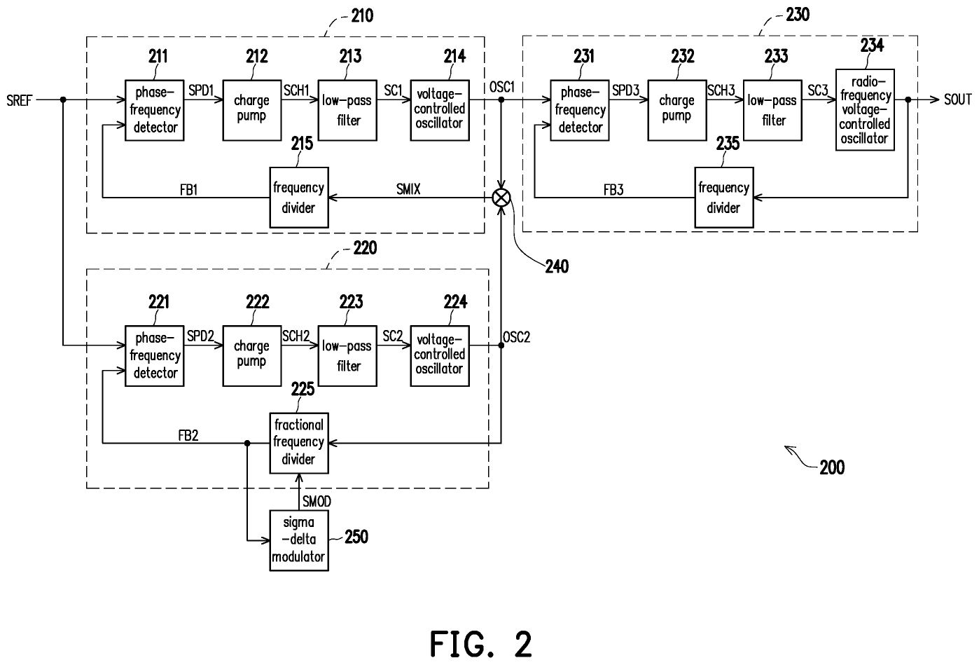

FIG. 2 is a circuit block diagram illustrating a frequency synthesizer according to one of the exemplary embodiments of the disclosure. Referring to FIG. 2, the frequency synthesizer 200 includes a jitter-cleaning phase-locked loop 210, a fractional phase-locked loop 220, a radio-frequency phase-locked loop 230, a mixer 240 and a sigma-delta modulator 250, but not limited thereto. The mixer 240 is coupled between the jitter-cleaning phase-locked loop 210 and the fractional phase-locked loop 220. The radio-frequency phase-locked loop 230 is coupled to the jitter-cleaning phase-locked loop 210. And the sigma-delta modulator 250 is coupled to the fractional phase-locked loop 220. In one embodiment of the disclosure, the frequency synthesizer 200 is configured to receive a reference clock SREF, and generate an output signal SOUT with a specific frequency range according to the reference clock SREF.

The jitter-cleaning phase-locked loop 210 includes a phase-frequency detector 211, a charge pump 212, a low-pass filter 213, a voltage-controlled oscillator 214 and a frequency divider 215, but not limited thereto. The phase-frequency detector 211 is configured to receive the reference clock SREF and a feedback signal FB1, and compare the reference clock SREF with the feedback signal FB1 to generate a phase difference signal SPD1. In short, when the phase-frequency detector 211 receives the reference clock SREF and the feedback signal FB1, the phase-frequency detector 211 compares the frequency phases of the reference clock SREF with the frequency phase of the feedback signal FB1, and generates the phase difference signal SPD1 according to the phase difference between the reference clock SREF and the feedback signal FB1.

The charge pump 212 is coupled to the phase-frequency detector 211. The charge pump 212 is configured to receive the phase difference signal SPD1 from the phase-frequency detector 211 to generate a charging signal SCH1. In some embodiments, the charge pump 212 can be a switching charge pump, but not limited thereto. In one embodiment of the disclosure, when the charge pump 212 receives the phase difference signal SPD1, the charge pump 212 can output a corresponding current pulse according to the phase difference signal SPD1 or generate a corresponding charging voltage based on the phase difference signal SPD1, which is not limited in the present disclosure.

The low-pass filter 213 is coupled to the charge pump 212. The low-pass filter 213 is configured to receive the charging signal SCH1 from the charge pump 212, and filter the charging signal SCH1 to generate a control signal SC1. In one embodiment of the disclosure, the low-pass filter 213 is used to filter off the high frequency noise in the charging signal SCH1 to generate the control signal SC1 with less noise. The type of the low-pass filter 213 is not limited in the disclosure.

The voltage-controlled oscillator 214 is coupled to the low-pass filter 213. The voltage-controlled oscillator 214 is configured to receive the control signal SC1 from the low-pass filter 213, and generate the first oscillating signal OSC1 according to the control signal SC1. In one embodiment of the disclosure, the frequency of the first oscillating signal OSC1 varies with the control signal SC1. In one embodiment of the disclosure, the voltage-controlled oscillator 214 is further configured to suppress a phase noise caused by the control signal SC1 to generate the first oscillating signal OSC1. In one embodiment of the disclosure, the voltage-controlled oscillator 214, for example, is a voltage-controlled crystal oscillator (VCXO) which has excellent phase noise performance. That is, the phase noise of the first oscillating signal OSC1 can be suppressed by the voltage-controlled oscillator 214 to implement the jitter-cleaning function.

The frequency divider 215 is coupled between the mixer 240 and the phase-frequency detector 211. The frequency divider 215 is configured to receive the mixed signal SMIX from the mixer 240 and perform a frequency-division to the mixed signal SMIX to generate the feedback signal FB1. In one embodiment of the disclosure, the frequency divider 215 is an integer frequency divider. An integer as a dividing factor provided by the frequency divider 215 is a positive integer. For example, in an application of the disclosure, the dividing factor provided by the frequency divider 215 is 2. In this case, when mixed signal SMIX is 245.76 MHz, the feedback signal FB1 would be 122.88 MHz. However, the value of the dividing factor is not limited in the present disclosure and can be determined according to the actual requirement.

Accordingly, assume the reference signal SREF sent from the baseband end has terrible phase noise. By setting the loop bandwidth of the jitter-cleaning phase-locked loop 210 to be extremely small and choosing the voltage-controlled oscillator 214 which have excellent phase noise performance, the phase noise of the first oscillating signal OSC1 will be reduced and the jitter-cleaning function can be achieved.

The fractional phase-locked loop 220 includes a phase-frequency detector 221, a charge pump 222, a low-pass filter 223, a voltage-controlled oscillator 224 and a fractional frequency divider 225, but not limited thereto. The phase-frequency detector 221 is configured to receive the reference clock SREF and a feedback signal FB2, and compare the reference clock SREF with the feedback signal FB2 to generate a phase difference signal SPD2. In short, when the phase-frequency detector 221 receives the reference clock SREF and the feedback signal FB2, the phase-frequency detector 221 compares the frequency phases of the reference clock SREF with the frequency phase of the feedback signal FB2, and generates the phase difference signal SPD2 according to the phase difference between the reference clock SREF and the feedback signal FB2.

The charge pump 222 is coupled to the phase-frequency detector 221. The charge pump 222 is configured to receive the phase difference signal SPD2 from the phase-frequency detector 221 to generate a charging signal SCH2. In some embodiments, the charge pump 222 can be a switching charge pump, but not limited thereto. In one embodiment of the disclosure, when the charge pump 222 receives the phase difference signal SPD2, the charge pump 222 can output a corresponding current pulse according to the phase difference signal SPD2 or generate a corresponding charging voltage based on the phase difference signal SPD2, which is not limited in the present disclosure.

The low-pass filter 223 is coupled to the charge pump 222. The low-pass filter 223 is configured to receive the charging signal SCH2 from the charge pump 222 and filter the charging signal SCH2 to generate a control signal SC2. Generally speaking, the low-pass filter 223 is used to filter off the high frequency noise in the charging signal SCH2 to generate the control signal SC2 with less noise. The type and the structure of the low-pass filter 223 are not limited in the disclosure.

The voltage-controlled oscillator 224 is coupled to the low-pass filter 223. The voltage-controlled oscillator 224 is configured to receive the control signal SC2 from the low-pass filter 223, and generate the second oscillating signal OSC2 according to the control signal SC2. In one embodiment of the disclosure, the frequency of the second oscillating signal OSC2 varies with the control signal SC2. In one embodiment of the disclosure, the voltage-controlled oscillator 224 is further configured to suppress a phase noise caused by the control signal SC2 to generate the second oscillating signal OSC2. In one embodiment of the disclosure, the voltage-controlled oscillator 224, for example, is a voltage-controlled crystal oscillator (VCXO) which has excellent phase noise performance. That is, the phase noise of the second oscillating signal OSC2 can be suppressed by the voltage-controlled oscillator 224.

The fractional frequency divider 225 is coupled between the voltage-controlled oscillator 224 and the phase-frequency detector 221. The fractional frequency divider 225 is configured to receive the second oscillating signal OSC2 from the voltage-controlled oscillator 224 and perform a fractional frequency-division to the second oscillating signal OSC2 to generate the feedback signal FB2. In one embodiment of the disclosure, the fractional frequency divider 225 can be a programmable fractional frequency divider, and a programmable fraction as a dividing factor is provided by the fractional frequency divider 225 to further increase the frequency resolution of the fractional phase-locked loop 220 by decreasing the channel spacing. However, the value of the dividing factor is not limited in the present disclosure and can be determined according to the actual requirement.

In some embodiments, the frequency synthesizer 200 can further include a sigma-delta modulator 250. The sigma-delta modulator 250 is coupled to the fractional phase-locked loop 220. The sigma-delta modulator 250 is configured to modulate a feedback signal FB2 sent from the fractional frequency divider 225 of the fractional phase-locked loop 220 to generate a modulated signal SMOD, and transmit the modulated signal SMOD back to the fractional frequency divider 225 of the fractional phase-locked loop 220. In one embodiment of the disclosure, the sigma-delta modulator 250 can modulate the dividing factor of the fractional frequency divider 225 and allow the noise shaping by oversampling the feedback signal FB2. As such, the dividing factor of the fractional frequency divider 225 can be dynamically modulated according to the feedback signal FB2 and the noise of the modulated signal SMOD can be reduced. The type and the structure of the sigma-delta modulator 250 are not limited in the disclosure.

The mixer 240 is coupled to the jitter-cleaning phase-locked loop 210 and the fractional phase-locked loop 220. The mixer 240 is configured to mix the first oscillating signal OSC1 from the jitter-cleaning phase-locked loop 210 and the second oscillating signal OSC2 from the jitter-cleaning phase-locked loop 210 to generate the mixed signal SMIX, and transmit the mixed signal SMIX to the frequency divider 215 of the jitter-cleaning phase-locked loop 210. In one embodiment of the disclosure, the mixer 240 can be implemented as a double-balanced mixer, but not limited thereto. In one embodiment of the disclosure, the mixer 240 mixes the first oscillating signal OSC1 with the frequency f1 and the second oscillating signal OSC2 with the frequency f2, and outputs the mixed signal SMIX with a sum or a differential between the frequency f1 and the frequency f2, which depends on the actual requirement.

For example, the fractional phase-locked loop 220 outputs the second oscillating signal OSC2 which its frequency f2 equal to (122.88+Δf) MHz. To satisfy the frequency of mixed signal SMIX equal to 245.76 MHz, the frequency f2 of the first oscillating signal OSC1 can be (122.88−Δf) MHz. It leads to the first oscillating signal OSC1 having low phase nose and high frequency resolution due to the excellent phase noise performance of the voltage-controlled oscillator 214 and voltage-controlled oscillator 224, the smaller channel spacing caused by the fractional phase-locked loop 220, and the dynamic modulation and the noise shaping implemented by the sigma-delta modulator 250.

It is noted that the fractional phase-locked loop 220 working with the sigma-delta modulator 250 may induce a quantization error. However, by combining the jitter-cleaning phase-locked loop 210 with the fractional phase-locked loop 220 through the mixer 240, the quantization error may be dramatically reduced due to twice filtering performed by the low-pass filter 213 and the low-pass filter 233.

The radio-frequency phase-locked loop 230 includes a phase-frequency detector 231, a charge pump 232, a low-pass filter 233, a radio-frequency voltage-controlled oscillator 234 and a frequency divider 235. The phase-frequency detector 231 is configured to receive the first oscillating signal OSC1 and a feedback signal FB3, and compare the first oscillating signal OSC1 with the feedback signal FB3 to generate a phase difference signal SPD3. In one embodiment of the disclosure, when the phase-frequency detector 231 receives the first oscillating signal OSC1 and the feedback signal FB3, the phase-frequency detector 231 compares the frequency phases of the first oscillating signal OSC1 with the frequency phase of the feedback signal FB3, and generates the phase difference signal SPD3 according to the phase difference between the first oscillating signal OSC1 and the feedback signal FB3.

The charge pump 232 is coupled to the phase-frequency detector 231. The charge pump 232 is configured to receive the phase difference signal SPD3 from the phase-frequency detector 231 to generate a charging signal SCH3. In some embodiments, the charge pump 232 can be a switching charge pump, but not limited thereto. Particularly, when the charge pump 232 receives the phase difference signal SPD3, the charge pump 232 can output a corresponding current pulse according to the phase difference signal SPD3 or generate a corresponding charging voltage based on the phase difference signal SPD3, which is not limited in the present disclosure.

The low-pass filter 233 is coupled to the charge pump 232. The low-pass filter 233 is configured to receive the charging signal SCH3 from the charge pump 232 and filter the charging signal SCH3 to generate a control signal SC3. Generally speaking, the low-pass filter 233 is used to filter off the high frequency noise in the charging signal SCH3 to generate the control signal SC3 with less noise. The type of the low-pass filter 233 is not limited in the disclosure.

The radio-frequency voltage-controlled oscillator 234 is coupled to the low-pass filter 233. The radio-frequency voltage-controlled oscillator 234 is configured to receive the control signal SC3 from the low-pass filter 233, and generate the output signal SOUT according to the control signal SC3. In one embodiment of the disclosure, the oscillation frequency of the output signal SOUT varies with the control signal SC3. In one embodiment of the disclosure, the radio-frequency voltage-controlled oscillator 234 can be a 3563.52 MHz voltage-controlled oscillator, but not limited thereto.

The frequency divider 235 is coupled between the radio-frequency voltage-controlled oscillator 234 and the phase-frequency detector 231. The frequency divider 235 is configured to receive the output signal SOUT from the radio-frequency voltage-controlled oscillator 234 and perform a frequency-division to the output signal SOUT to generate the feedback signal FB3. In one embodiment of the disclosure, the frequency divider 235 is an integer frequency divider. An integer as a dividing factor provided by the frequency divider 235 is a positive integer. For example, in an application of the present disclosure, the dividing factor provided by the frequency divider 235 is 29. In this case, when the feedback signal FB3 is about 122.88 MHz, the output signal SOUT is 3563.52 MHz. However, the value of the dividing factor is not limited in the present disclosure and can be determined according to the actual requirement.

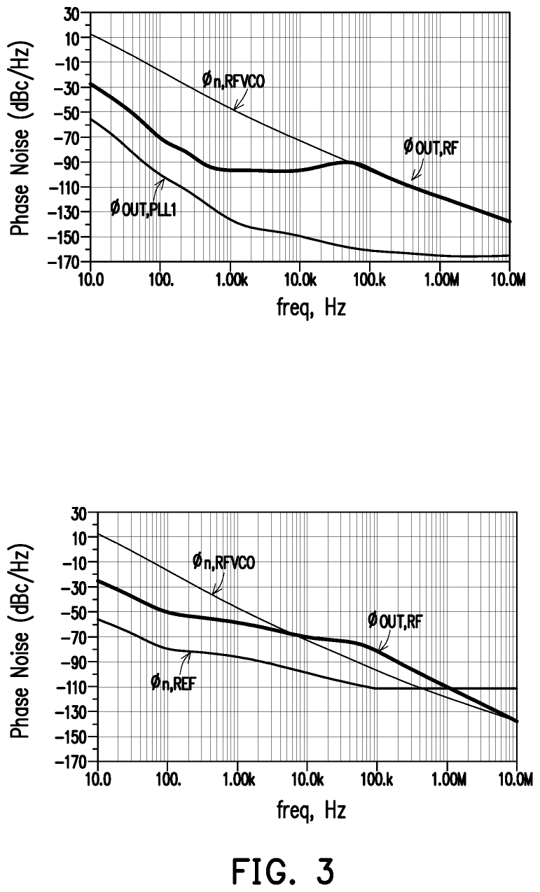

FIG. 3 are bode plots which illustrates improvement of phase noise by using the frequency synthesizer according of one of the exemplary embodiments of the disclosure. Referring to FIG. 3, the upper figure and the lower figure of FIG. 3 are the bode plots by using the first oscillating signal OSC1 and the reference clock SREF as the input of the radio-frequency phase-locked loop, respectively. Φ_{n,RFVCO} is the phase noise of the radio-frequency voltage-controlled oscillator, Φ_{OUT,PLL1} is the phase noise of the first oscillating signal OSC1, Φ_{n,REF} is the phase noise of the reference clock SREF, and Φ_{OUT,RF} is the phase noise of the output signal. It can be observed that Φ_{OUT,RF} would be successfully improved by using the frequency synthesizer according of one of the exemplary embodiments of the disclosure.

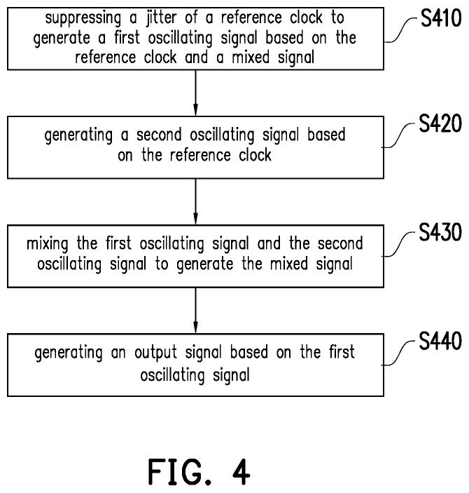

FIG. 4 illustrates a flow chart of a frequency synthesizing method according to one of the exemplary embodiments of the disclosure. The frequency synthesizing method used by a frequency synthesizer with a jitter cleaning function which the frequency synthesizer includes a jitter-cleaning phase-locked loop, a fractional phase-locked loop, a mixer, and a radio-frequency phase-locked loop. In step S410, the jitter-cleaning phase-locked loop suppresses a jitter of a reference clock to generate a first oscillating signal based on the reference clock and a mixed signal. Next, in step S420, the fractional phase-locked loop generates a second oscillating signal based on the reference clock. In step S430, the mixer mixes the first oscillating signal and the second oscillating signal to generate the mixed signal. In step S440, the radio-frequency phase-locked loop generates an output signal based on the first oscillating signal.

Base on above, by combining the jitter-cleaning phase-locked loop with the fractional phase-locked loop, the frequency synthesizer suppress the jitter of the reference clock and provide high frequency resolution. The frequency synthesizer can be implemented to be a local frequency generator of the radio transceiver of the fifth generation wireless communication system.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A frequency synthesizer, comprising:
a jitter-cleaning phase-locked loop, comprising a voltage-controlled oscillator, configured to receive a reference clock and a mixed signal, and suppress a jitter of the reference clock to generate a first oscillating signal based on the reference clock and the mixed signal, wherein the voltage-controlled oscillator is a voltage-controlled crystal oscillator;
a fractional phase-locked loop, comprising another voltage-controlled oscillator, configured to receive the reference clock, and generate a second oscillating signal based on the reference clock, wherein the another voltage-controlled oscillator is another voltage-controlled crystal oscillator;
a mixer, coupled to the jitter-cleaning phase-locked loop and the fractional phase-locked loop, configured to mix the first oscillating signal and the second oscillating signal to generate the mixed signal; and
a radio-frequency phase-locked loop, coupled to the jitter-cleaning phase-locked loop, configured to receive the first oscillating signal, and generate an output signal based on the first oscillating signal.

2. The frequency synthesizer as claimed in claim 1, wherein the frequency synthesizer further comprises:
a sigma-delta modulator, coupled to the fractional phase-locked loop, configured to modulate a feedback signal received from the fractional phase-locked loop to generate a modulated signal, and transmit the modulated signal to the fractional phase-locked loop.

3. The frequency synthesizer as claimed in claim 1, wherein the jitter-cleaning phase-locked loop comprises:
a phase-frequency detector, configured to receive the reference clock and a feedback signal, and compare the reference clock with the feedback signal to generate a phase difference signal;
a charge pump, coupled to the phase-frequency detector, configured to charge the phase difference signal to the generate a charging signal;
a low-pass filter, coupled to the charge pump, configured to filter the charging signal to generate a control signal; and
the voltage-controlled oscillator, coupled between the low-pass filter and the mixer, configured to receive the control signal, and generate the first oscillating signal according to the control signal.

4. The frequency synthesizer as claimed in claim 3, wherein the jitter-cleaning phase-locked loop further comprises:
a frequency divider, coupled between the mixer and the phase-frequency detector, configured to perform a frequency-division to the mixed signal to generate the feedback signal.

5. The frequency synthesizer as claimed in claim 3, wherein the voltage-controlled oscillator suppresses phase noise caused by the control signal to generate the first oscillating signal.

6. The frequency synthesizer as claimed in claim 2, wherein the fractional phase-locked loop comprises:
a phase-frequency detector, configured to receive the reference clock and a feedback signal, and compare the reference clock with the feedback signal to generate a phase difference signal;
a charge pump, coupled to the phase-frequency detector, configured to charge the phase difference signal to the generate a charging signal;
a low-pass filter, coupled to the charge pump, configured to filter the charging signal to generate a control signal; and
the another voltage-controlled oscillator, coupled between the low-pass filter and the mixer, configured to receive the control signal, and generate the second oscillating signal according to the control signal.

7. The frequency synthesizer as claimed in claim 6, wherein the fractional phase-locked loop further comprises:
a fractional frequency divider, coupled between the another voltage-controlled oscillator and the phase-frequency detector, configured to receive the second oscillating signal and the modulated signal, and perform a fractional frequency-division to the second oscillating signal to generate the feedback signal based on the second oscillating signal and the modulated signal.

8. The frequency synthesizer as claimed in claim 6, wherein the another voltage-controlled oscillator suppresses a phase noise caused by the control signal to generate the second oscillating signal.

9. The frequency synthesizer as claimed in claim 1, wherein the radio-frequency phase-locked loop comprises:
a phase-frequency detector, coupled to the jitter-cleaning phase-locked loop, configured to receive the first oscillating signal and a feedback signal, and compare the first oscillating signal with the feedback signal to generate a phase difference signal;
a charge pump, coupled to the phase-frequency detector, configured to charge the phase difference signal to the generate a charging signal;
a low-pass filter, coupled to the charge pump, configured to filter the charging signal to generate a control signal; and
a radio-frequency voltage-controlled oscillator, coupled to the low-pass filter, configured to receive the control signal, and generate the output signal according to the charging signal.

10. The frequency synthesizer as claimed in claim 9, wherein the radio-frequency phase-locked loop further comprises:
a frequency divider, coupled between the radio-frequency voltage-controlled oscillator and the phase-frequency detector, configured to perform a frequency-division to the output signal to generate the feedback signal.

11. A frequency synthesizing method used by a frequency synthesizer, wherein the frequency synthesizer comprises a jitter-cleaning phase-locked loop, a fractional phase-locked loop, a mixer, and a radio-frequency phase-locked loop, the method comprising:
suppressing, by the jitter-cleaning phase-locked loop, a jitter of a reference clock to generate a first oscillating signal based on the reference clock and a mixed signal, wherein the jitter-cleaning phase-locked loop comprises a voltage-controlled oscillator, and the voltage-controlled oscillator is a voltage-controlled crystal oscillator;
generating, by the fractional phase-locked loop, a second oscillating signal based on the reference clock, wherein the fractional phase-locked loop comprises another voltage-controlled oscillator, and the another voltage-controlled oscillator is another voltage-controlled crystal oscillator;
mixing, by the mixer, the first oscillating signal and the second oscillating signal to generate the mixed signal; and
generating, by the radio-frequency phase-locked loop, an output signal based on the first oscillating signal.

12. The frequency synthesizing method as claimed in claim 11, wherein the frequency synthesizing method further comprises:
modulating, by a sigma-delta modulator, a feedback signal received from the fractional phase-locked loop to generate a modulated signal; and
transmitting, by the sigma-delta modulator, the modulated signal to the fractional phase-locked loop.

13. The frequency synthesizing method as claimed in claim 11, wherein the step of suppressing, by a jitter-cleaning phase-locked loop, a jitter of the reference clock to generate a first oscillating signal based on the reference clock and the mixed signal comprises:
comparing, by a phase-frequency detector, the reference clock with a feedback signal to generate a phase difference signal;
charging, by a charge pump, the phase difference signal to the generate a charging signal;
filtering, by a low-pass filter, the charging signal to generate a control signal; and
generating, by the voltage-controlled oscillator, the first oscillating signal according to the control signal.

14. The frequency synthesizing method as claimed in claim 13,
wherein the step of suppressing, by a jitter-cleaning phase-locked loop, a jitter of the reference clock to generate a first oscillating signal based on the reference clock and the mixed signal further comprises:
performing, by a frequency divider, a frequency-division to the mixed signal to generate the feedback signal.

15. The frequency synthesizing method as claimed in claim 13, wherein the voltage-controlled oscillator suppresses phase noise caused by the control signal to generate the first oscillating signal.

16. The frequency synthesizing method as claimed in claim 12, wherein the step of generating, by a fractional phase-locked loop, a second oscillating signal based on the reference clock comprises:
comparing, by a phase-frequency detector, the reference clock with the feedback signal to generate a phase difference signal;
charging, by a charge pump, the phase difference signal to the generate a charging signal;
filtering, by a low-pass filter, the charging signal to generate a control signal; and
generating, by the another voltage-controlled oscillator, the second oscillating signal according to the control signal.

17. The frequency synthesizing method as claimed in claim 16, wherein the step of generating, by a fractional phase-locked loop, a second oscillating signal based on the reference clock further comprises:
performing, by a fractional frequency divider, a fractional frequency-division to the second oscillating signal to generate the feedback signal based on the second oscillating signal and the modulated signal.

18. The frequency synthesizing method as claimed in claim 16, wherein the another voltage-controlled oscillator suppresses phase noise caused by the control signal to generate the second oscillating signal.

19. The frequency synthesizing method as claimed in claim 11, wherein the step of generating, by a radio-frequency phase-locked loop, an output signal based on the first oscillating signal comprises:
comparing, by a phase-frequency detector, the first oscillating signal with a feedback signal to generate a phase difference signal;
charging, by a charge pump, the phase difference signal to the generate a charging signal;
filtering, by a low-pass filter, the charging signal to generate a control signal; and
generating, by a radio-frequency voltage-controlled oscillator, the output signal according to the charging signal.

20. The frequency synthesizing method as claimed in claim 19, wherein the step of generating, by a radio-frequency phase-locked loop, an output signal based on the first oscillating signal further comprises:
performing, by a frequency divider, a frequency-division to the output signal to generate the feedback signal.
